(19) United States
(12) Patent Application Publication
(10) Pub. No.: US 2005/0127793 A1
(43) Pub. Date: Jun. 16, 2005

(54) Acoustic backing material for small-element ultrasound transducer arrays

(76) Inventors: Charles E. Baumgartner, Niskayuna, NY (US); David M. Mills, Niskayuna, NY (US)

Correspondence Address: Dennis M. Flaherty;Ostrager Chong & Flaherty LLP, 30th Floor, 825 Third Avenue, New York, NY, 10022-7519, US

(21) Appl. No.: 10/737,216

(22) Filed: Dec. 15, 2003

(51) Int. Cl. H01L 41/08

(52) U.S. Cl. 310/334

(57) ABSTRACT

A fine-pitch acoustic transducer array that has a backing made of acoustically attenuative material. The backing material is prepared by homogeneously combining a matrix component and filler components having an average particle size less than one-fifth (preferably less than one-tenth) of the smallest dimension of the elements making up the array. In certain embodiments, the acoustically attenuative material comprises 25-45 wt. % tungsten particles, 15-35 wt. % silicone particles and 40-60 wt. % epoxy.

### BACKGROUND OF THE INVENTION

This invention generally relates to ultrasound transducer arrays. In particular, the invention relates to ultrasound transducer arrays comprising small elements, such as small-element arrays used in ultrasound imaging.

Conventional ultrasound imaging transducers generate acoustic energy via a piezoelectric effect in which electrical energy is converted into acoustic energy using a poled piezoelectric ceramic material. The acoustic energy that is transmitted in the forward direction, which is in the direction of the patient being scanned, is coupled to the patient through one or more acoustic matching layers. However, the acoustic energy transmitted in the direction away from the patient being scanned is typically absorbed in and/or scattered by an acoustic backing material (also referred to herein as “acoustically attenuative material”) located on the backside of the transducer array. This prevents the acoustic energy from being reflected from structures or interfaces behind the transducer and back into the piezoelectric material, thereby reducing the quality of the acoustic image obtained from reflection within the patient.

More specifically, piezoelectric ultrasound transducer arrays operated in a pulse echo mode require a backing material to attenuate the acoustic energy that is propagated in the reverse direction, i.e., away from the patient. Common acoustic backing materials are combinations of a high-density acoustic scatterer, such as titanium dioxide or tungsten metal, and/or a soft acoustic absorbing material, such as silicone, in a matrix of an epoxy or a polyurethane. The backing material may be either preformed and attached to the back surface of the transducer or cast and cured in place. Acoustic properties, principally acoustic impedance and attenuation, are critical properties that must be optimized along with the remaining acoustic stack to maximize probe performance.

Conventional ultrasound elements, such as those found in linear and multi-row acoustic probes, possess a larger element size in elevation that can tolerate a larger local disparity in backing material composition. However small piezoelectric elements such as those found in a two-dimensional or multi-row high-frequency transducer array, require a significantly greater level of backing material uniformity.

Electrical connection to small elements in a two-dimensional ultrasound transducer array may be obtained by laminating together alternate layers of a flexible printed circuit and acoustic backing material to form a z-axis electrical connector, as disclosed in International Publication No. WO 02/040184 A3 and U.S. Patent Application Publication No. 2003/0085635 to Davidsen. In this case the acoustic backing material possesses additional requirements in terms of particle size, homogeneity, and inelastic compressibility, in addition to the acoustic properties.

Whereas conventional ultrasound transducer elements are larger in elevation than in the azimuthal dimension, the element size in a two-dimensional ultrasound transducer array may have a dimension of 300 microns or smaller. In order to maintain acoustic uniformity across the transducer array, each of these small elements must be backed with essentially the same backing material composition. Therefore the particle size of the additives used to adjust the acoustic impedance and attenuation must be significantly smaller than the element size. In addition, for a z-axis electrical connector formed using a pressure lamination process, the final element pitch is determined from the total thickness of the two components, i.e., the flex circuits and layers of acoustic backing material. The inelastic compressibility of the acoustic backing material, which comprises the major portion (by volume) of this structure, must be sufficiently small under the lamination conditions so as to not lead to a significant change in the final pitch.

There is a need for an acoustic backing material that meets the foregoing constraints.

### BRIEF DESCRIPTION OF THE INVENTION

The present invention is directed to a fine-pitch acoustic transducer array that has a backing made of acoustically attenuative material prepared by homogeneously combining a matrix component and filler components having a particle size less than one-fifth (preferably less than one-tenth) of the smallest dimension of the elements making up the array. In accordance with certain embodiments of the invention, the acoustically attenuative material comprises 25-45 wt. % tungsten particles, 15-35 wt. % silicone particles and 40-60 wt. % epoxy.

It should be understood at the outset that the aspects of the invention disclosed herein are not limited to piezoelectric ceramic transducer elements, but rather apply to any array having fine-pitch ultrasound transducer elements. In particular, the elements in a two-dimensional transducer array may have a dimension (e.g., width or diameter) on the order of 300 microns or smaller. Other types of transducer elements that may be used in conjunction with the acoustic backing disclosed herein include micromachined ultrasound transducers of the capacitive (cMUTs) and piezoelectric (pMUTs) varieties.

One aspect of the invention is an ultrasonic transducer device comprising: an element that converts impinging acoustic energy into outputted electrical energy and that converts inputted electrical energy into outgoing acoustic energy, and a body of acoustically attenuative material that is acoustically coupled to the element, wherein the acoustically attenuative material comprises particles of an acoustic scattering material having an average diameter less than 20 microns and particles of an acoustic absorbing material having an average diameter less than 20 microns, the particles of acoustic scattering and absorbing material being dispersed in a matrix.

Another aspect of the invention is an ultrasound transducer array comprising a multiplicity of ultrasound transducer elements and a layer of acoustically attenuative material that is acoustically coupled to back surfaces of the ultrasound transducer element, wherein each of the ultrasound transducer elements converts impinging acoustic energy into outputted electrical energy and that converts inputted electrical energy into outgoing acoustic energy, and the acoustically attenuative material comprises particles of an acoustic scattering material having an average diameter less than 20 microns and particles of an acoustic absorbing material having an average diameter less than 20 microns, the particles of acoustic scattering and absorbing material being substantially homogeneously dispersed in a matrix.

A further aspect of the invention is a laminated acoustic backing comprising a multiplicity of flexible circuits with acoustically attenuative material therebetween, each of the flexible circuits comprising a respective thin layer of electrically insulative material having a respective multiplicity of electrically conductive traces formed thereon, and the acoustically attenuative material comprising particles of an acoustic scattering material having an average diameter less than 20 microns and particles of an acoustic absorbing material having an average diameter less than 20 microns, the particles of acoustic scattering and absorbing material being substantially homogeneously dispersed in a matrix.

Yet another aspect of the invention is an ultrasonic transducer device comprising: an element that converts impinging acoustic energy into outputted electrical energy and that converts inputted electrical energy into outgoing acoustic energy, the element having a smallest element dimension equal to 300 microns or less, and a body of acoustically attenuative material that is acoustically coupled to the element, wherein the acoustically attenuative material comprises particles of an acoustic scattering material having an average diameter less than 20% of the smallest element dimension and particles of an acoustic absorbing material having an average diameter less than 20% of the smallest element dimension, the particles of acoustic scattering and absorbing material being dispersed in a matrix.

Other aspects of the invention are disclosed and claimed below.

### BRIEF DESCRIPTION OF THE DRAWINGS

FIG. 1 is a drawing showing one element of an ultrasound transducer array having an acoustic backing layer acoustically coupled to the rear surfaces of the transducer elements.

FIG. 2 is a microphotograph of an acoustic backing material in accordance with one embodiment of the present invention.

### DETAILED DESCRIPTION OF THE INVENTION

For the purpose of illustration, various embodiments of the invention will be described that belong to the class of piezoelectric ceramic ultrasonic transducers. However, it should be understood that the aspects of the invention disclosed herein also have application in other types of fine-pitch ultrasound transducer arrays, such as cMUTs and pMUTs.

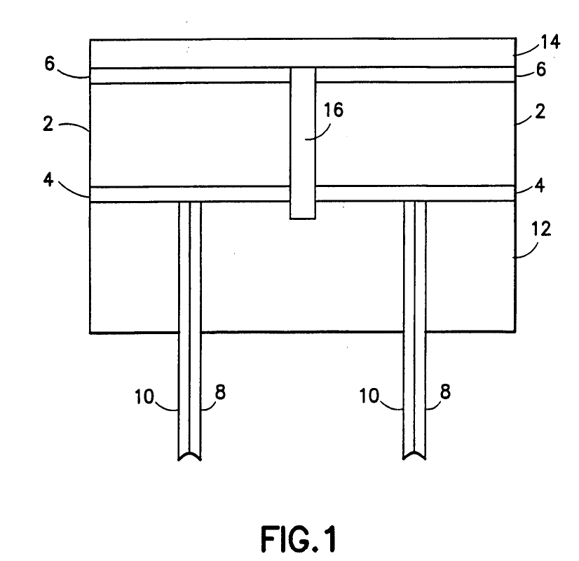

FIG. 1 shows an exemplary ultrasound transducer element comprising a piezoelectric ceramic layer 2 having a bottom surface that has been metallized to form a signal electrode 4 and a top surface that has been metallized to form a ground electrode 6. An acoustic impedance matching layer 14 made of electrically conductive material is joined to the metallized top surface of the ceramic by a thin (acoustically transparent) layer of epoxy (not shown) that allows ohmic contact between the matching layer 14 and the ground electrode 6. As partly depicted in FIG. 1, matching layer 14 is common to all transducer elements, meaning that it covers the entire array and is in electrical contact with the ground electrodes of all transducer elements in the array, only two transducer elements being shown in FIG. 1. If more than one acoustic impedance matching layer is placed at the front of the metallized ceramic, then the inner matching layer should be electrically conductive or have an electrically conductive layer for connecting the ground electrodes.

The transducer array is set over a patterned array of electrical signal connectors. One example of such an array of electrical connectors is a series of spaced and mutually parallel flex circuits embedded within an acoustic backing layer 12, only a portion of which is shown in FIG. 1, such that the ends of each trace 8 imprinted on each dielectric substrate 10 (e.g., Kapton® polyimide film) are exposed at the surface of the acoustic backing layer. In a two-dimensional array, the transducer elements of each column are respectively electrically connected to traces arrayed on a respective dielectric substrate. Thus there will be one flex circuit per column in the transducer array. FIG. 1 shows two flex circuits corresponding to two columns of ultrasound transducer elements and also shows only one metal trace 8 on each dielectric substrate 10 electrically connected to a respective transducer element in each column.

The acoustic backing layer 12 is joined to the metallized bottom surface of the ceramic by a thin (acoustically transparent) layer of epoxy (not shown) that allows ohmic contact between the signal electrode 4 and the exposed end of the metal trace 8. Alternatively, a metal pad may be formed over the exposed end of the metal trace, with ohmic contact then occurring between the signal electrode and the metal pad. Preferably, the acoustic backing layer is joined to the transducer array layer before the respective columns are diced and before the acoustic impedance matching layer is installed. In that event, the saw may cut to a depth that enters the acoustic backing layer 12, as seen in FIG. 1. A representative kerf 16 is shown in FIG. 1. The kerf 16 acoustically isolates the transducer elements in one column from the adjacent transducer elements in adjacent columns. Kerf 16 also electrically isolates the signal electrodes 4 of adjacent transducers in adjacent columns. Dicing in an orthogonal direction will produce kerfs (not shown) that acoustically isolate the transducer elements of a given row from each other and that electrically isolates the signal electrodes of those same transducer elements.

Acoustic transducers with fine pitch possess unique requirements for the backing material used to attenuate acoustic power in the direction away from the patient being imaged. The small dimensions of the acoustic element and the need for homogeneous performance across the face of the array mandate a homogeneous backing material with small particle sized fillers. The backing material must also possess an acoustic impedance and attenuation sufficient to function as an acoustic backing material to the transducer array. A further complication for connection to a two-dimensional electrical connector manufactured by laminating together alternating layers of flexible circuits and acoustic backing material, is the ability to preform the acoustic backing material to a set thickness and then to hold that thickness throughout the lamination process. This set of requirements represents a unique set of properties for an ultrasound acoustic backing material.

The foregoing set of requirements is met by an acoustic backing material comprised of silicone beads and tungsten particles, both of which possess an average particle size less than 20% and preferably less than 10% (and most preferably less than 5%) of the smallest element dimension, homogeneously dispersed in an epoxy matrix with a glass transition temperature significantly higher than the maximum lamination temperature. As used herein (and in the claims), the term “element dimension” refers to the element dimension in the elevational or azimuthal direction (e.g., the width, length or diameter of the element), and not in the depth direction.

The acoustic backing materials herein are prepared by homogeneously combining a matrix component and filler components, the latter having a particle size of less than one-fifth of the smallest piezoelectric element dimension and preferably less than one-tenth (most preferably one-twentieth) of the smallest piezoelectric element dimension. The acoustic properties of the backing material are a function of the local backing density, which in turn is determined principally by the selection of the filler material and the relative ratio of the filler to the matrix. The thermal properties of the backing material, on the other hand, are principally determined by the selected matrix material. In accordance with one family of embodiments of the invention, the acoustic backing material comprises 40 to 60% by weight of an epoxy, 25 to 45% by weight of a tungsten powder, and 15 to 35% by weight of a finely dispersible silicone powder. In addition, both the tungsten powder and the silicone powder possess respective average particle sizes of less than 20 microns. In other embodiments, the high-density tungsten particles may be replaced by TiO₂, Al₂O₃ or other high-density particles of less than 20 microns in average size.

In order to assist dispersion of the silicone powder into the matrix epoxy, it is preferred that the silicone be in the form of non-agglomerated (i.e., spherical) powder or beads. An example of the silicone beads is Tospearl™ spherical silicone supplied by GE/Toshiba Silicones. However, other sources of silicone in which the silicone is present as a discrete particle in spherical or similar form are also useful in this composition.

The epoxy is selected from a broad class of materials which may be aromatic or aliphatic organic molecules possessing one or more epoxy functionalities, which is in turn cross-linked with a standard curative such as an amine or an anhydride. One example of this is the diepoxide of bisphenol-A formed by reaction with epichlorohydrin, which is cross-linked with an aliphatic amine.

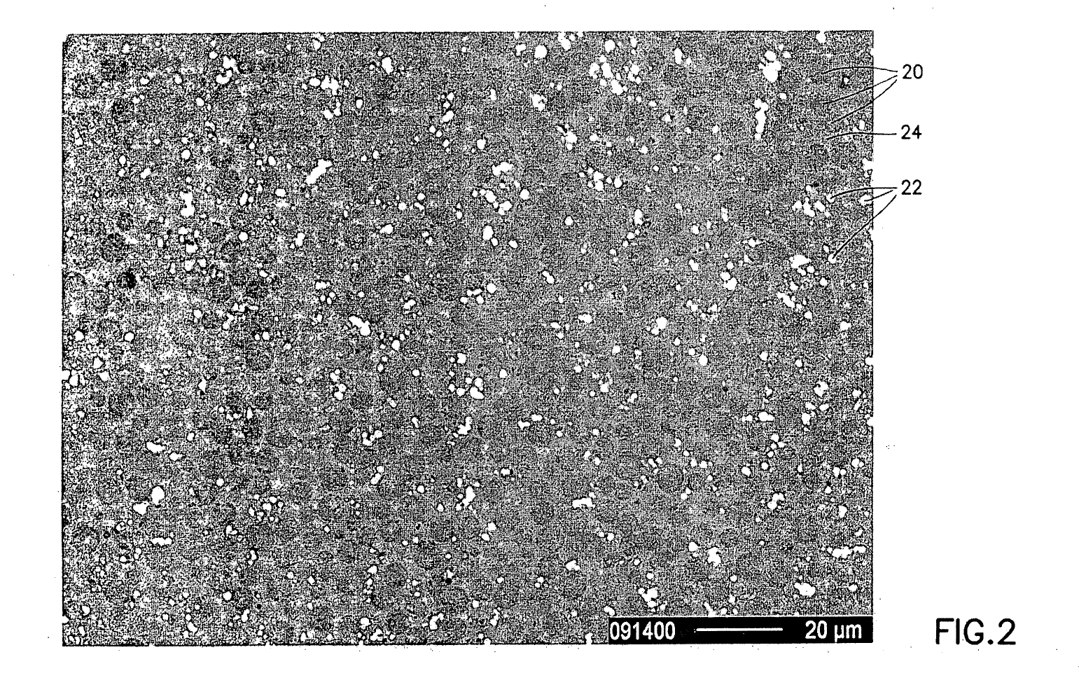

In one embodiment of the invention, an acoustic backing material was prepared using a homogeneous mixture of 45 wt. % tungsten powder with an average particle size of approximately 5 microns, 15 wt. % of silicone beads with an average particle size of less than 10 microns, and 40 wt. % of an epoxy matrix prepared from a bisphenol-A epoxy and an aliphatic amine curative. The amine curative was selected to yield a final glass transition temperature significantly above the highest processing temperature to which the cured backing material would be exposed during manufacturing. This composition yielded an acoustic impedance of 4.2 Mrayls and an acoustic attenuation at 5 MHz of −3.1 dB/mm. A photomicrograph of the acoustic backing material prepared with this composition is shown in FIG. 2. Silicone beads are indicated by reference numeral 20, the smaller tungsten particles (which appear white) are indicated by reference numeral 22, and the surrounding epoxy matrix is indicated reference numeral 24. The acoustic attenuating backing material homogeneity is sufficient to allow for uniform attenuation and impedance across an entire acoustic array even if the array possesses numerous small elements.

The foregoing composition can be changed to vary both the attenuation and impedance by changing either the tungsten-to-silicone ratio or the total filler content. Alternatively, micron-sized powders of a lower density than tungsten can be either added or substituted for tungsten to further reduce the acoustic impedance while maintaining the acoustic attenuation.

It is important that the acoustic backing material be comprised of small-particle-sized fillers such that the backing material is uniform in composition relative to the size of the acoustic element. It is also important that the backing material impedance and attenuation be optimized as part of the total acoustic stack. One embodiment of this is a backing material prepared from micron-particle-sized tungsten powder and micron-particle-sized silicone powder dispersed within an epoxy matrix. Superior dispersion is obtained when the silicone powder is spherical in nature.

While the invention has been described with reference to preferred embodiments, it will be understood by those skilled in the art that various changes may be made and equivalents may be substituted for elements thereof without departing from the scope of the invention. In addition, many modifications may be made to adapt a particular situation to the teachings of the invention without departing from the essential scope thereof. Therefore it is intended that the invention not be limited to the particular embodiment disclosed as the best mode contemplated for carrying out this invention, but that the invention will include all embodiments falling within the scope of the appended claims.

As used in the claims, the term “ultrasonic transducer” encompasses capacitive or piezoelectric ultrasonic transducers.

1. An ultrasonic transducer device comprising:
an element that converts impinging acoustic energy into outputted electrical energy and that converts inputted electrical energy into outgoing acoustic energy; and
a body of acoustically attenuative material that is acoustically coupled to said element, wherein said acoustically attenuative material comprises particles of an acoustic scattering material having an average diameter less than 20 microns and particles of an acoustic absorbing material having an average diameter less than 20 microns, said particles of acoustic scattering and absorbing material being dispersed in a matrix.

2. The ultrasonic transducer device as recited in claim 1, wherein said acoustic scattering material comprises tungsten.

3. The ultrasonic transducer device as recited in claim 1, wherein said acoustic scattering material further comprises a material having a density lower than the density of tungsten.

4. The ultrasonic transducer device as recited in claim 2, wherein said material having a density lower than tungsten is TiO₂.

5. The ultrasonic transducer device as recited in claim 4, wherein said matrix comprises epoxy.

6. The ultrasonic transducer device as recited in claim 1, wherein said acoustically attenuative material comprises 25-45 wt. % tungsten particles, 15-35 wt. % silicone particles and 40-60 wt. % epoxy.

7. The ultrasonic transducer device as recited in claim 1, wherein said acoustic absorbing material is silicone.

8. The ultrasonic transducer device as recited in claim 7, wherein said silicone particles are in the form of non-agglomerated powder or beads.

9. The ultrasonic transducer device as recited in claim 7, wherein the shape of said silicone particles is substantially spherical.

10. The ultrasonic transducer device as recited in claim 5, wherein said epoxy is selected from the group consisting of aromatic or aliphatic organic molecules that have been cross-linked with a curative taken from the group consisting of an amine or an anhydride.

11. The ultrasonic transducer device as recited in claim 10, wherein said epoxy comprises the diepoxide of bisphenol-A formed by reaction with epichlorohydrin and said curative comprises an aliphatic amine.

12. The ultrasonic transducer device as recited in claim 5, wherein said epoxy has a glass transition temperature at least 20° C. above the maximum processing temperature to which said acoustically attenuative material is exposed.

13. An ultrasound transducer array comprising a multiplicity of ultrasound transducer elements and a layer of acoustically attenuative material that is acoustically coupled to back surfaces of said ultrasound transducer element, wherein each of said ultrasound transducer elements converts impinging acoustic energy into outputted electrical energy and that converts inputted electrical energy into outgoing acoustic energy, and said acoustically attenuative material comprises particles of an acoustic scattering material having an average diameter less than 20% of the smallest element dimension and particles of an acoustic absorbing material having an average diameter less than 20% of the smallest element dimension, said particles of acoustic scattering and absorbing material being substantially homogeneously dispersed in a matrix.

14. The ultrasonic transducer array as recited in claim 13, wherein said acoustic scattering material is tungsten, said acoustic absorbing material is silicone and said matrix is made of an epoxy.

15. The ultrasonic transducer array as recited in claim 14, wherein said acoustically attenuative material comprises 25-45 wt. % tungsten particles, 15-35 wt. % silicone particles and 40-60 wt. % epoxy.

16. The ultrasonic transducer array as recited in claim 14, wherein said silicone particles are in the form of non-agglomerated powder or beads.

17. The ultrasonic transducer array as recited in claim 14, wherein the shape of said silicone particles is substantially spherical.

18. The ultrasonic transducer array as recited in claim 14, wherein said epoxy is selected from the group consisting of aromatic or aliphatic organic molecules that have been cross-linked with a curative taken from the group consisting of an amine or an anhydride.

19. The ultrasonic transducer array as recited in claim 18, wherein said epoxy comprises the diepoxide of bisphenol-A formed by reaction with epichlorohydrin and said curative comprises an aliphatic amine.

20. The ultrasonic transducer array as recited in claim 14, wherein said epoxy has a glass transition temperature at least 20° C. above the maximum processing temperature to which said acoustically attenuative material is exposed.

21. The ultrasonic transducer array as recited in claim 13, further comprising a thin layer of electrically insulative material having a multiplicity of electrically conductive traces formed thereon, at least a portion of said thin layer being embedded in said acoustically attenuative material, and each of said traces being electrically connected to an electrode of a respective ultrasound transducer element.

22. A laminated acoustic backing comprising a multiplicity of flexible circuits with pre-cured sheets of acoustically attenuative material therebetween, each of said flexible circuits comprising a respective thin layer of electrically insulative material having a respective multiplicity of electrically conductive traces formed thereon, and said acoustically attenuative material comprising particles of an acoustic scattering material having an average diameter less than 20% of the smallest element dimension and particles of an acoustic absorbing material having an average diameter less than 20% of the smallest element dimension, said particles of acoustic scattering and absorbing material being substantially homogeneously dispersed in a matrix

23. The laminated acoustic backing as recited in claim 22, wherein said acoustically attenuative material possesses an inelastic compressibility of less than 1% during the lamination process.

24. The laminated acoustic backing as recited in claim 25, wherein said acoustically attenuative material comprises 25-45 wt. % tungsten particles, 15-35 wt. % silicone particles and 40-60 wt. % epoxy.

25. The laminated acoustic backing as recited in claim 24, wherein the shape of said silicone particles is substantially spherical.

26. The laminated acoustic backing as recited in claim 24, wherein said epoxy is selected from the group consisting of aromatic or aliphatic organic molecules that have been cross-linked with a curative taken from the group consisting of an amine or an anhydride.

27. The laminated acoustic backing as recited in claim 26, wherein said epoxy comprises the diepoxide of bisphenol-A formed by reaction with epichlorohydrin and said curative comprises an aliphatic amine.

28. The laminated acoustic backing as recited in claim 24, wherein said epoxy has a glass transition temperature at least 20° C. above the maximum processing temperature to which said acoustically attenuative material is exposed.

27. An ultrasonic transducer device comprising:
an element that converts impinging acoustic energy into outputted electrical energy and that converts inputted electrical energy into outgoing acoustic energy, said element having a smallest element dimension equal to 300 microns or less; and
a body of acoustically attenuative material that is acoustically coupled to said element, wherein said acoustically attenuative material comprises particles of an acoustic scattering material having an average diameter less than 20% of the smallest element dimension and particles of an acoustic absorbing material having an average diameter less than 20% of the smallest element dimension, said particles of acoustic scattering and absorbing material being dispersed in a matrix.
